(19) United States
(12) Patent Application Publication
(10) Pub. No.: US 2021/0280522 A1
(43) Pub. Date: Sep. 9, 2021

(54) MULTI-MOLDING METHOD FOR FAN-OUT STACKED SEMICONDUCTOR PACKAGE

(71) Applicant: Powertech Technology Inc., Hukou Township (TW)

(72) Inventor: Sheng-Jie LIU, Hukou Township (TW)

(73) Assignee: Powertech Technology Inc., Hukou Township (TW)

(21) Appl. No.: 16/890,859

(22) Filed: Jun. 2, 2020

(30) Foreign Application Priority Data
Mar. 4, 2020 (TW) 109107148

(51) Int. Cl. H01L 23/538; H01L 23/31; H01L 23/00; H01L 21/683; H01L 21/48; H01L 21/56; H01L 21/78

(52) U.S. Cl. CPC H01L 23/5389; H01L 23/3128; H01L 23/5383; H01L 23/5386; H01L 24/20; H01L 24/19; H01L 2224/214; H01L 21/4853; H01L 21/4857; H01L 21/565; H01L 21/568; H01L 21/78; H01L 2221/68372; H01L 21/6835

(57) ABSTRACT

A multi-molding method for fan-out stacked semiconductor package is disclosed. Two molding chambers with different sizes are provided. Multiple first packages made in front-end packaging process are placed in a first molding chamber with smaller size to form a first molding compound. After then, multiple second packages made in back-end are placed in a second molding chamber with larger size to form a second molding compound. The second molding compound encapsulates the first molding compound. Therefore, the multi-molding method of the present invention is adapted to be used in fan-out panel level package process without an expensive compression mold tape.

### CROSS-REFERENCE TO RELATED APPLICATIONS

This application is based upon and claims priority under 35 U.S.C. 119 from Taiwan Patent Application No. 109107148 filed on Mar. 4, 2020, which is hereby specifically incorporated herein by this reference thereto.

### BACKGROUND OF THE INVENTION

### 1. Field of the Invention

The present invention relates to a molding method for a fan-out stacked semiconductor package. It is especially referred to a multi-molding method for a fan-out stacked semiconductor package.

### 2. Description of the Prior Arts

A stacked semiconductor package 80 molded by the wafer level package process is shown in FIG. 2. The stacked semiconductor package primarily includes a first redistribution layer 81, a bottom chip 82, two top chips 83 and a second redistribution layer 84, wherein the bottom chip 82 is bonded to the second redistribution layer 84 and a first compound 85 is formed to encapsulate the bottom chip 82 by molding resin. Afterwards, the first redistribution layer 81 is formed on the first compound 85, and both of the top chips 83 are flip-chip bonded to the first redistribution layer 81. Next adopting a compression mold tape encapsulates both of the top chips 83 to produce a second compound 90.

The cost of the compression mold tape is more expensive than that of the molding resin and no compression mold tape is available in the supply chain for the 500 mm (width) carrier adopted by the fan-out panel level package process yet. Therefore, it would be a bottle neck needing further improvement for the second compound molded from the fan-out panel level package process.

To overcome the shortcomings, the present invention provides a multi-molding method for a fan-out stacked semiconductor package to mitigate or to obviate the aforementioned problems.

### SUMMARY OF THE INVENTION

An objective of the present invention is to provide a multi-molding method for fan-out stacked semiconductor package.

To achieve the objective as mentioned above, the multi-molding method for fan-out stacked semiconductor package has the steps of:

(a) providing a carrier for a fan-out semiconductor level package;

(b) forming multiple first packages on the carrier;

(c) placing the multiple first packages in a first molding chamber to form a first molding compound encapsulating the first packages;

(d) forming a first redistribution layer on an exposed surface of the first molding compound;

(e) forming multiple second packages on the first redistribution layer;

(f) placing the first molding compound, the first redistribution layer and the second packages in a second molding chamber to form a second molding compound encapsulating the first molding compound and the first redistribution layer; wherein the second molding chamber is larger than the first molding chamber;

(g) removing the carrier; and

(h) executing a singulation process to produce multiple fan-out stacked semiconductor packages.

From the above description, the present invention primarily provides two kinds of molding chambers with different sizes. Multiple first packages are placed in a first molding chamber to form a first molding compound at first, then multiple second packages are formed and placed in a second larger molding chamber to form the second molding compound which encapsulates the first molding compound. As a result, the multi-molding method of the present invention is adapted to be used in the fan-out panel level package process with larger area of the carrier instead of the usage of the expensive compression mold tape.

Other objectives, advantages and novel features of the invention will become more apparent from the following detailed description when taken in conjunction with the accompanying drawings.

### BRIEF DESCRIPTION OF THE DRAWINGS

FIGS. 1A to 1H are multiple cross-sectional views in different steps of a multi-molding method for a fan-out stacked semiconductor package of the present invention; and

FIG. 2 is a cross-sectional view of the stacked semiconductor package molded by the conventional wafer level package manufacturing process.

### DETAILED DESCRIPTION OF THE EMBODIMENTS

The present invention relates to a multi-molding method for fan-out stacked semiconductor package, multiple embodiments are illustrated with the figures below to describe the amendment for the multi-molding method for fan-out stacked semiconductor package of the invention in detail.

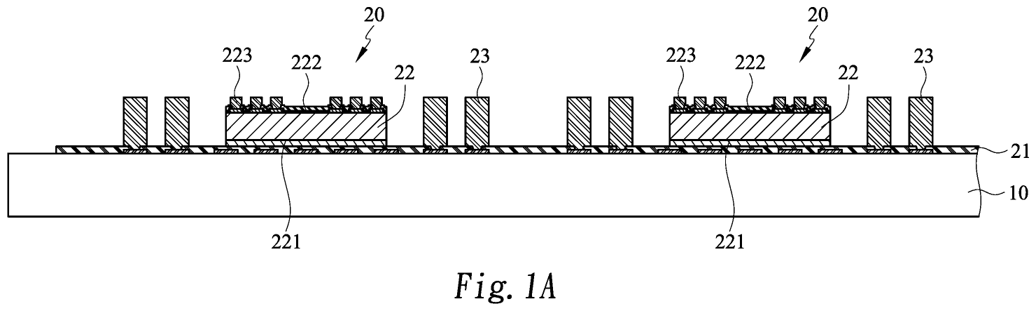

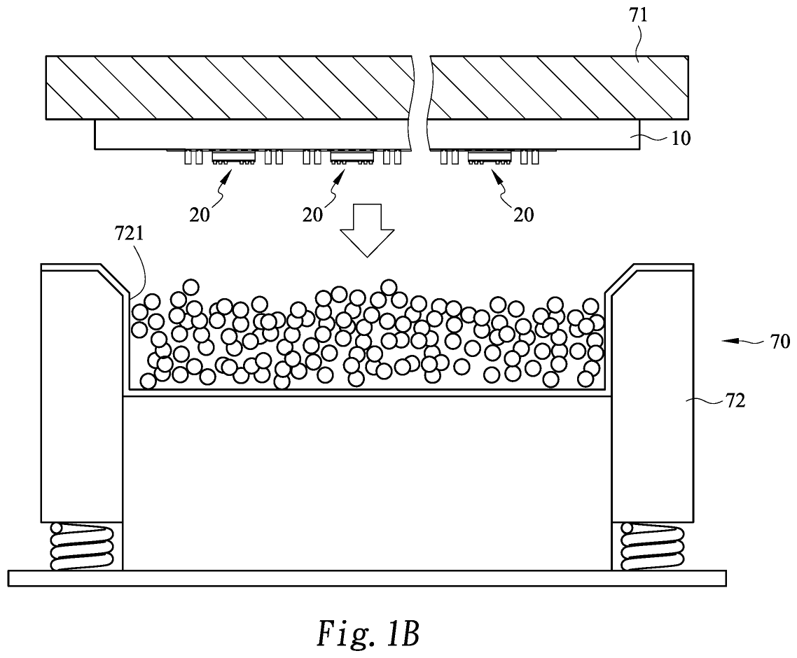

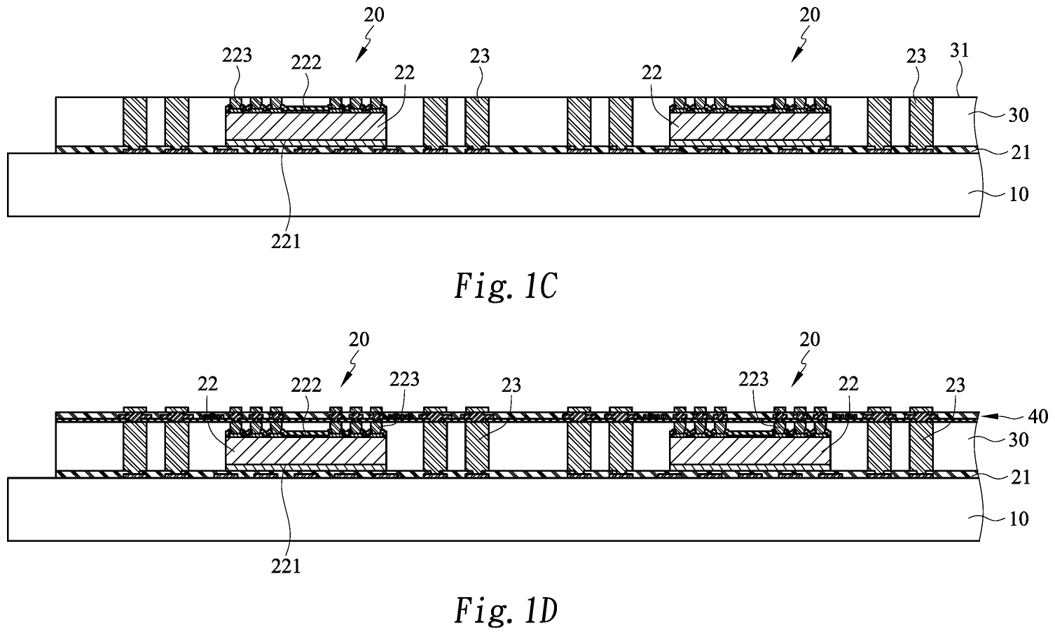

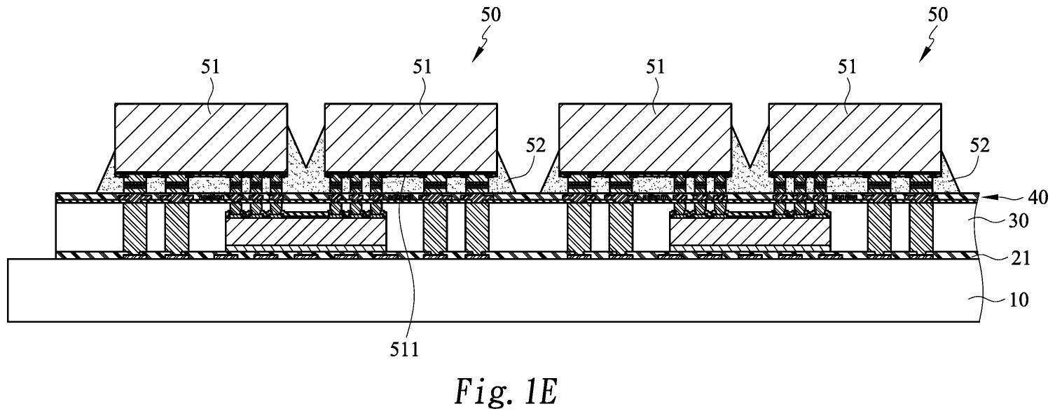

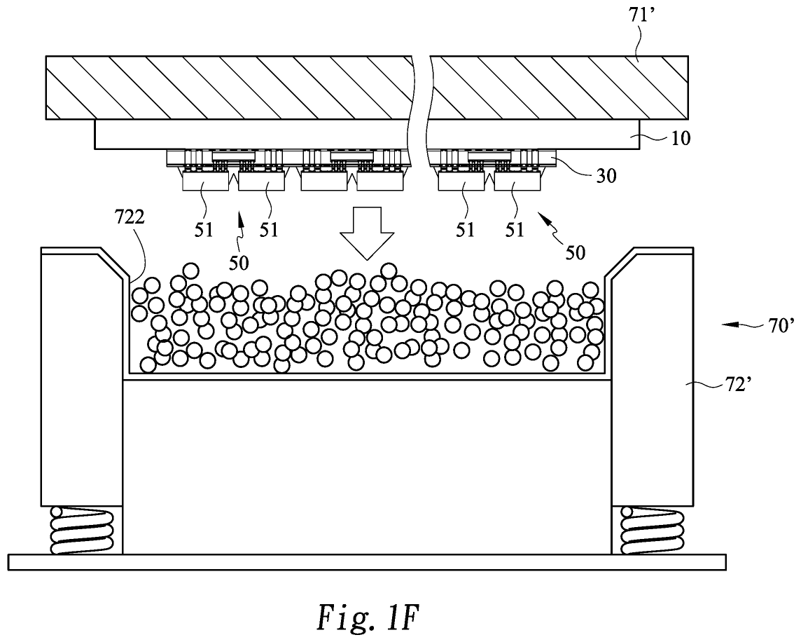

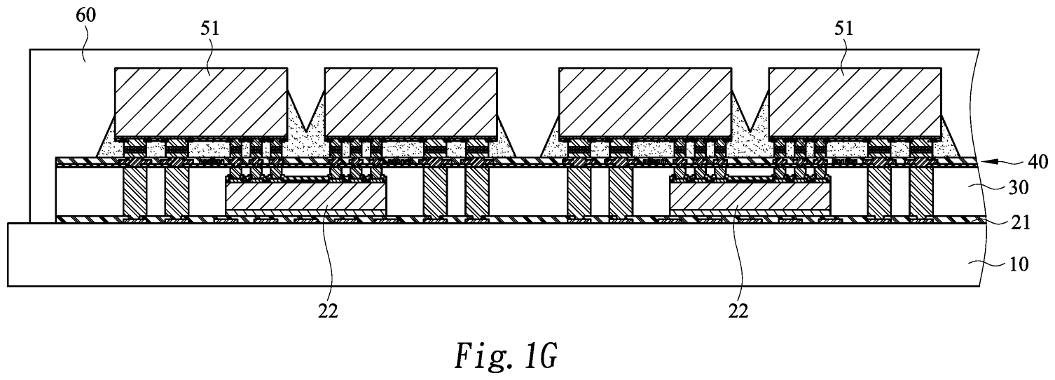

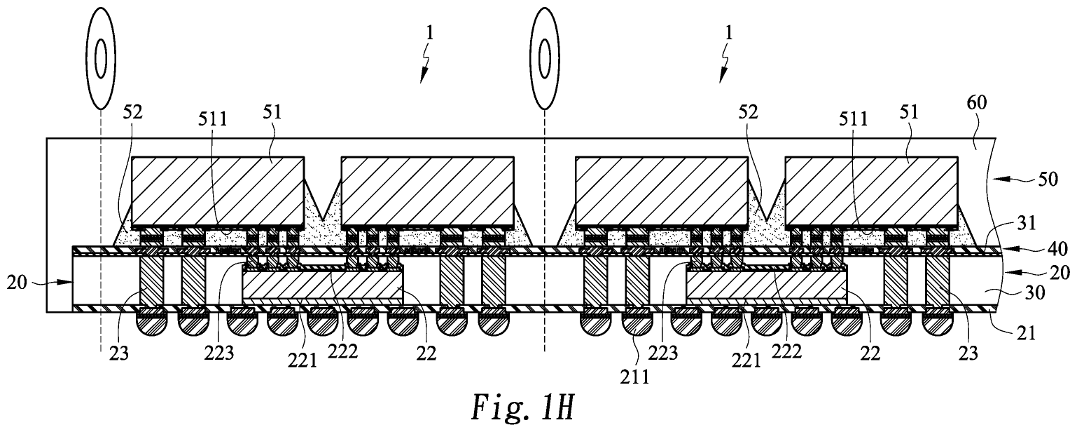

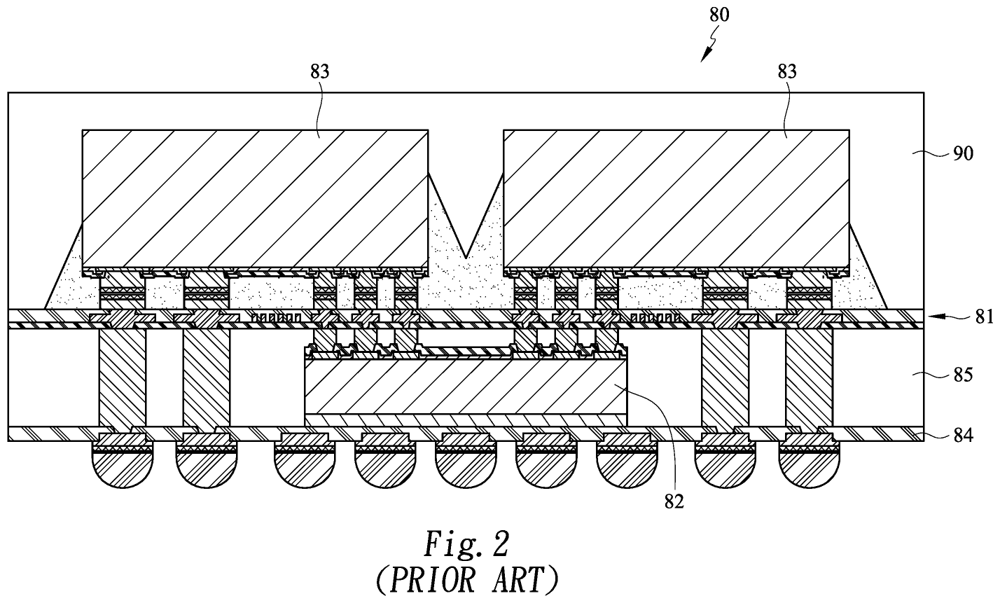

With reference to FIGS. 1A to 1H, a multi-molding method for fan-out stacked semiconductor package in accordance with the invention is illustrated and has the following step (a) to step (h).

In the step (a), as shown in FIG. 1A, a carrier 10 is provided for a fan-out semiconductor level package. In the embodiment, the carrier 10 is adapted for a fan-out panel level package process and a width of the carrier is larger than 500 mm.

In the step (b), as shown in FIG. 1A, multiple first packages 20 are formed on the carrier 10. In the embodiment, the step (b) further includes the following step (b1) to step (b3). A second redistribution layer 21 is formed on the carrier 10 in the step (b1). In the step (b2), multiple rear faces of multiple first chips 22 are adhered on the second redistribution layer 21 and multiple bumps 223 are respectively formed on multiple pads of an active face 222 of each first chip 22. In the step (b3), multiple metal pillars 23 are formed on the second redistribution layer 21 and around each of the first chips 22. The metal pillars 23 are electrically connected to the second redistribution layer 21. Multiple free ends of the metal pillars 23 and the bumps 223 are coplanar.

In the step (c), as shown in FIG. 1B, the first packages 20 are placed in a first molding chamber 721 to form a first molding compound 30. And the first molding compound 30 encapsulates the multiple first packages 20 as shown in the FIG. 1C. In the embodiment, as shown in FIG. 1B, a mold device 70 having a top mold 71 and a bottom mold 72 is prepared, wherein the carrier 10 as well as the first packages 20 are located at the top mold 71, and the bottom mold 72 further has the first molding chamber 721. After the top mold 71 is disposed to cover the first molding chamber 721 of the bottom mold 72, the first molding compound 30 is formed. Preferably, after the first packages 20 with the first encapsulation 30 are taken from the mold device 70, an exposed surface 31 of the first molding compound 30 and the free ends of the metal pillars 23 and the bumps 223 are coplanar. Preferably, the size of the first molding chamber 721 is 489.8 mm×480.9 mm.

In the step (d), as shown in FIG. 1C and FIG. 1D, a first redistribution layer 40 is formed on an exposed surface 31 of the first molding compound 30. The first redistribution layer 40 is electrically connected to the metal pillars 23 as well as the bumps 223 of the multiple first packages 20.

In the step (e), as shown in FIG. 1D and FIG. 1E, multiple second packages 50 are formed on the first redistribution layer 40. In the embodiment, each of the second packages 50 has two second chips 51 each of which has an active face. Both of the active faces of the second chips 51 are disposed towards the first redistribution layer 40 and electrically connected to the first redistribution layer 40. Afterwards, a underfill 52 is filled between the active face 511 of the at least one second chip 51 of each of the second molding compound 50 and the first redistribution layer 40.

In the step (f), as shown in FIG. 1E and FIG. 1F, the first molding compound 30, the first redistribution layer 40 and the second packages 50 are placed in a second molding chamber 722 to form a second molding compound 60. As shown in FIG. 1E and FIG. 1G, the second molding compound 60 thoroughly encapsulates the first molding compound 30, the underfill 52 and the first redistribution layer 40, wherein the second molding chamber 722 is larger than the first molding chamber 721. In the embodiment, as shown in FIG. 1F, a mold device 70′ having a top mold 71′ and a bottom mold 72′ is prepared, wherein the carrier 10 as well as the second packages 50 are located at the top mold 71′, and the bottom mold 72′ further has the second molding chamber 722. After the top mold 71′ is disposed to cover the second molding chamber 722 of the bottom mold 72′, the second molding compound 60 is formed. Preferably, the size of the second molding chamber 722 is 501.8 mm×492.9 mm which is available for the placement of the carrier having the width around 500 mm. As a result, the multi-molding method of the present invention may include two sizes of molding chambers, however, it would not be limited to the other available embodiment that adopts one adjustable bottom molding chamber for the sequential molding packages.

In the step (g), as shown in FIG. 1H, the carrier 10 is removed and a surface of the first molding compound 20 is correspondingly exposed to the carrier 10. Sequentially multiple outer connections 211 are formed on the exposed surface of the first molding compound 20. In the embodiment, after the carrier 10 is removed, the second redistribution layer 21 is exposed where the solder balls are formed on it. The solder balls are used as the outer connections 211.

In the step (h), as shown in FIG. 1H, the singulation process is executed to produce the multiple fan-out stacked semiconductor packages 1. At last, parts of the first resin 30 and the second resin 60 at the terminal side of the carrier 10 are cut off.

In summary, the multi-molding method of the present invention for the fan-out panel level package process primarily includes preparing two different sizes of molding chambers. Multiple first packages are placed in a first molding chamber to form a first molding compound at first, then multiple second packages are formed and placed in a relatively larger second molding chamber to form a second molding compound which encapsulates the first molding compound. Therefore, the multi-molding method of the present invention is adapted to be used in the fan-out panel level package process without an expensive compression mold tape.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A multi-molding method for fan-out stacked semiconductor package, comprising:
(a) providing a carrier for a fan-out semiconductor level package;
(b) forming multiple first packages on the carrier;
(c) placing the multiple first packages in a first molding chamber to form a first molding compound encapsulating the first packages;
(d) forming a first redistribution layer on an exposed surface of the first molding compound;
(e) forming multiple second packages on the first redistribution layer;
(f) placing the first molding compound, the first redistribution layer and the second packages in a second molding chamber to form a second molding compound encapsulating the first molding compound and the first redistribution layer; wherein the second molding chamber is larger than the first molding chamber;
(g) removing the carrier; and
(h) executing a singulation process to produce multiple fan-out stacked semiconductor packages.

2. The multi-molding method as claimed in claim 1, wherein a surface of the first molding compound corresponding to the carrier is exposed and multiple outer connections are formed on the exposed surface of the first molding compound after removing the carrier in the step (g).

3. The multi-molding method as claimed in claim 1, wherein the step (b) further comprising:
(b1) forming a second redistribution layer on the carrier;
(b2) adhering multiple rear faces of multiple first chips on the second redistribution layer, wherein multiple bumps are respectively formed on multiple pads of an active face of each of the first chips; and
(b3) forming multiple metal pillars on the second redistribution layer and around each of the first chips; wherein the metal pillars are electrically connected to the second redistribution layer, multiple free ends of the metal pillars and the bumps are coplanar.

4. The multi-molding method as claimed in claim 2, wherein the step (b) further comprising:
(b1) forming a second redistribution layer on the carrier;
(b2) adhering multiple rear faces of multiple first chips on the second redistribution layer, wherein multiple bumps are respectively formed on multiple pads of an active face of each of the first chips; and
(b3) forming multiple metal pillars on the second redistribution layer and around each of the first chips; wherein the metal pillars are electrically connected to the second redistribution layer, multiple free ends of the metal pillars and the bumps are coplanar.

5. The multi-molding method as claimed in claim 3, wherein the exposed surface of the first molding compound and the free ends of the metal pillars and the bumps are coplanar in the step (c).

6. The multi-molding method as claimed in claim 4, wherein the exposed surface of the first molding compound and the free ends of the metal pillars and the bumps are coplanar in the step (c).

7. The multi-molding method as claimed in claim 5, wherein the first redistribution layer is electrically connected to the metal pillars and the bumps in the step (d).

8. The multi-molding method as claimed in claim 6, wherein the first redistribution layer is electrically connected to the metal pillars and the bumps in the step (d).

9. The multi-molding method as claimed in claim 7, wherein each of the second packages having an active face of the at least one second chip disposed towards the first redistribution layer and electrically connected to the first redistribution layer in the step (e).

10. The multi-molding method as claimed in claim 8, wherein each of the second packages having an active face of the at least one second chip disposed towards the first redistribution layer and electrically connected to the first redistribution layer in the step (e).

11. The multi-molding method as claimed in claim 5, wherein an underfill is filled between an active face of the at least one second chip of each of the second packages and the first redistribution layer in the step (e).

12. The multi-molding method as claimed in claim 6, wherein an underfill is filled between an active face of the at least one second chip of each of the second packages and the first redistribution layer in the step (e).

13. The multi-molding method as claimed in claim 7, wherein the second molding compound further encapsulates the underfill in the step (f).

14. The multi-molding method as claimed in claim 8, wherein the second molding compound further encapsulates the underfill in the step (f).

15. The multi-molding method as claimed in claim 3, wherein each of the outer connections is a solder ball in the step (f).

16. The multi-molding method as claimed in claim 4, wherein each of the outer connections is a solder ball in the step (f).

17. The multi-molding method as claimed in claim 1, wherein:
a width of the carrier in the step (a) is larger than or equal to 500 mm;
a width of the second molding chamber is larger than or equal to 500 mm; and
a width of the first molding chamber is smaller than 500 mm.
